(19) United States
(12) Patent Application Publication
(10) Pub. No.: US 2026/0162948 A1
(43) Pub. Date: Jun. 11, 2026

(54) SUBSTRATE SUPPORT UNIT AND SUBSTRATE PROCESSING APPARATUS INCLUDING THE SAME

(71) Applicant: SEMES CO., LTD., Cheonan-si (KR)

(72) Inventors: Jae Kyung LEE, Cheonan-si (KR); Dae Hyun KWAK, Cheonan-si (KR); Sung Ho LEE, Cheonan-si (KR); Sang Woo KIM, Cheonan-si (KR)

(73) Assignee: SEMES CO., LTD., Cheonan-si (KR)

(21) Appl. No.: 19/411,356

(22) Filed: Dec. 7, 2025

(30) Foreign Application Priority Data
Dec. 9, 2024 (KR) 10-2024-0181773

(51) Int. Cl. H01J 37/32; H01J 9/30

(52) U.S. Cl. CPC H01J 37/32715; H01J 9/30; H01J 37/32568; H01J 37/32577; H01J 37/32853; H01J 2237/2007

(57) ABSTRACT

Disclosed are a substrate support unit and a substrate processing apparatus including the same, in which a heat generation issue of a bias electrode is improved. The substrate support unit is disposed inside a chamber body for processing of a substrate using plasma to hold the substrate, and includes a dielectric plate including a chucking electrode for adsorption of the substrate, a bias electrode provided inside the dielectric plate at a position below the chucking electrode to control plasma treatment process characteristics, and a bias power line configured to supply power to the bias electrode. The bias power line branches into a plurality of lines, and the plurality of lines forms junction portions together with the bias electrode in a region outside the substrate.

### CROSS-REFERENCE TO THE RELATED APPLICATION

The present application claims priority to and the benefit of Korean Patent Application No. 10-2024-0181773, filed on Dec. 9, 2024, in the Korean Intellectual Property Office, the entire disclosure of which is incorporated herein by reference.

### BACKGROUND

### 1. Field

The present disclosure relates to a substrate support unit and a substrate processing apparatus including the same, in which a heat generation issue of a bias electrode is improved.

### 2. Description of the Related Art

A substrate processing apparatus is generally used to perform a predetermined processing operation on a substrate such as a semiconductor wafer in order to manufacture a semiconductor device. The predetermined processing operation includes a deposition process of forming a predetermined film on a substrate surface, an etching process of forming a predetermined pattern on the film formed on the substrate, and a cleaning process of physically or chemically cleaning the substrate surface.

The substrate processing apparatus includes a substrate support unit configured to support a substrate. As the substrate support unit, an electrostatic chuck that electrostatically adsorbs and fixes a substrate is commonly used. The electrostatic chuck includes a dielectric plate, which includes a chucking electrode embedded therein and adsorbs and supports the lower surface of a substrate, and a metal base plate, which is disposed below the dielectric plate and functions as a lower electrode for plasma generation or as a substrate cooling unit. The dielectric plate and the base plate are bonded to each other using an adhesive layer.

In the substrate processing apparatus, plasma treatment is performed by supplying a process gas to the inside of a chamber and applying radio-frequency (RF) power to a substrate support unit so that the process gas is excited to an energy level higher than a reference energy level. In the excited state, plasma is generated, and a substrate adsorbed on the substrate support unit undergoes plasma treatment.

Recently, plasma treatment has been performed under high-power conditions with respect to bias power for ion introduction. However, ionization occurs in a heat transfer gas supplied to a substrate or a focus ring, resulting in abnormal discharge at a lower surface of the substrate or the focus ring. When high bias power is applied to a lower electrode, a potential difference is generated between the lower electrode and the substrate and between the lower electrode and the focus ring, depending on the capacitance between the lower electrode and the substrate and the capacitance between the lower electrode and the focus ring. The potential difference causes ionization in the heat transfer gas supplied to the lower surfaces of the substrate and the focus ring, leading to abnormal discharge.

In order to solve such a problem, Korean Patent Laid-Open Publication No. 10-2020-0144488 discloses a technique of mounting a bias electrode below a chucking electrode. When bias power is applied to the bias electrode, the capacitance between the bias electrode and the substrate and between the bias electrode and the focus ring may be increased compared to a configuration in which bias power is applied to a lower electrode, and a potential difference between the substrate and the focus ring may be reduced. In addition, fluctuation of the potential between the substrate and the focus ring may be suppressed, thereby preventing abnormal discharge of a heat transfer gas supplied to the lower surface of the substrate.

In order to apply high power to the bias electrode, a central bias power line is disposed so as to pass through a central portion of the substrate support unit. The bias power line passes through the base plate and is electrically connected to a disc-shaped bias electrode mounted on the dielectric plate. However, heat is generated at the junction between the bias power line having a relatively large diameter and the thin disc-shaped bias electrode, which leads to process defects that affect the substrate.

When high power is applied, a transient high current flows through the bias power line, generating Joule heating at the junction between the bias electrode and the bias power line. As a result, process defects occur at the central portion of the substrate at which the bias power line is located. Because the bias electrode is mounted inside the dielectric plate adsorbing the substrate and is positioned close to the underside of the substrate, temperature non-uniformity caused by the Joule heating at the junction affects the substrate and serves as a factor that reduces semiconductor yield.

### RELATED ART DOCUMENT

### Patent Document

(Patent Document 1) KR 10-2020-0144488 A (December 29, 2020)

### SUMMARY

The present disclosure is directed to providing a substrate support unit and a substrate processing apparatus including the same, in which a heat generation issue occurring at a junction portion between a bias electrode and a bias power line during a substrate processing operation is improved.

In particular, the present disclosure is directed to providing a substrate support unit and a substrate processing apparatus including the same, in which the bias power line branches into a plurality of lines, and a plurality of lines is connected to the bias electrode in a region outside a substrate, thereby addressing a heat generation issue during a process of supplying bias power.

A substrate support unit according to an embodiment of the present disclosure is disposed inside a chamber body for processing of a substrate using plasma to hold the substrate, and includes a dielectric plate including a chucking electrode for adsorption of the substrate, a bias electrode provided inside the dielectric plate at a position below the chucking electrode to control plasma treatment process characteristics, and a bias power line configured to supply power to the bias electrode. The bias power line branches into a plurality of lines, and the plurality of lines forms junction portions together with the bias electrode in a region outside the substrate.

In an embodiment of the present disclosure, the power supplied through the bias power line may be supplied by a direct-current power supply or a radio-frequency power supply.

In an embodiment of the present disclosure, the substrate support unit may further include a base plate disposed below the dielectric plate and functioning as a support and an adhesive layer joining the dielectric plate and the base plate to each other, and the plurality of lines branching from the bias power line may be arranged inside the adhesive layer and may extend to the junction portions with the bias electrode.

In an embodiment of the present disclosure, the bias electrode may extend in a diameter direction to an edge of the substrate.

In an embodiment of the present disclosure, the bias power line may branch into additional lines, and the additional lines may form junction portions together with the bias electrode in a region inside the substrate.

In an embodiment of the present disclosure, the junction portions may be formed through brazing.

In an embodiment of the present disclosure, the substrate support unit may further include a brazing cover provided at each of the junction portions and configured to hold a filler metal, melted by brazing, at each of the junction portions.

In an embodiment of the present disclosure, the brazing cover may include a cover body having a disc shape, a line holder formed at a central portion of the cover body so as to receive the bias power line fitted thereinto, and an outer wall formed to a predetermined height along an outer circumference of the cover body, and the filler metal may be held in a recess defined by the cover body and the outer wall.

In an embodiment of the present disclosure, the outer wall may have an end forming an outer circumferential surface to allow an adhesive for brazing to be applied thereto.

In an embodiment of the present disclosure, the filler metal may be selected from among aluminum, titanium, chromium, molybdenum, gold, lead, and tantalum.

In an embodiment of the present disclosure, the brazing cover may further include a protrusion protruding to a predetermined height into the recess so as to allow the filler metal to be fitted into the protrusion before brazing heat treatment.

In an embodiment of the present disclosure, each of the plurality of lines branching from the bias power line may have a plurality of trenches formed in an end thereof to be joined to the bias electrode, the plurality of trenches serving to accelerate capillary action during a brazing process.

In an embodiment of the present disclosure, each of the plurality of trenches may have a depth of 0.02 to 0.1 mm.

In accordance with another aspect of the present disclosure, a substrate processing apparatus includes a chamber body for processing of a substrate using plasma and a substrate support unit disposed inside the chamber body to hold the substrate. The substrate support unit includes a dielectric plate including a chucking electrode for adsorption of the substrate, a bias electrode provided inside the dielectric plate at a position below the chucking electrode to control plasma treatment process characteristics, and a bias power line configured to supply power to the bias electrode. The bias power line branches into a plurality of lines, and the plurality of lines forms junction portions together with the bias electrode in a region outside the substrate.

In an embodiment of the present disclosure, the substrate support unit may further include a base plate disposed below the dielectric plate and functioning as a support and an adhesive layer joining the dielectric plate and the base plate to each other, and the plurality of lines branching from the bias power line may be arranged inside the adhesive layer and may extend to the junction portions with the bias electrode.

In an embodiment of the present disclosure, the bias electrode may extend in a diameter direction to an edge of the substrate.

In an embodiment of the present disclosure, the junction portions may be formed through brazing, and the substrate support unit may further include a brazing cover provided at each of the junction portions and configured to hold a filler metal, melted by brazing, at each of the junction portions. The brazing cover may include a cover body having a disc shape, a line holder formed at a central portion of the cover body so as to receive the bias power line fitted thereinto, and an outer wall formed to a predetermined height along an outer circumference of the cover body. The filler metal may be held in a recess defined by the cover body and the outer wall.

In an embodiment of the present disclosure, each of the junction portions may be formed by performing a cleaning step of removing contaminants from the bias electrode, the brazing cover, and the bias power line, a flux application step for prevention of oxidation during brazing heat treatment, a brazing cover assembly step of fitting an end of the bias power line to be joined into the line holder, a filler metal fitting step of fitting the filler metal into a protrusion protruding from an end of the liner holder into the recess, and a brazing step of performing heat treatment to form each of the junction portions.

In an embodiment of the present disclosure, the brazing step may include a step of temporarily adhering an assembly of the brazing cover and the bias power line at a position for formation of each of the junction portions of the bias electrode.

In accordance with another aspect of the present disclosure, a substrate processing apparatus includes a chamber body for processing of a substrate using plasma and a substrate support unit disposed inside the chamber body to hold the substrate. The substrate support unit includes a dielectric plate including a chucking electrode for adsorption of the substrate, a base plate disposed below the dielectric plate and functioning as a support, an adhesive layer joining the dielectric plate and the base plate to each other, a bias electrode provided inside the dielectric plate at a position below the chucking electrode to control plasma treatment process characteristics, the bias electrode extending in a diameter direction to an edge of the substrate adsorbed on and held by the dielectric plate, and a bias power line configured to supply power to the bias electrode. The bias power line branches into a plurality of lines, and the plurality of lines forms a plurality of junction portions together with the bias electrode in a region outside the substrate and a region inside the substrate. The plurality of lines branching from the bias power line is arranged inside the adhesive layer and extends to the plurality of junction portions with the bias electrode. The plurality of junction portions is formed through brazing, and the substrate support unit further includes a brazing cover provided at each of the plurality of junction portions and configured to hold a filler metal, melted by heat treatment, at each of the plurality of junction portions. The brazing cover includes a cover body having a disc shape, a line holder formed at a central portion of the cover body so as to receive the bias power line fitted thereinto, and an outer wall formed to a predetermined height along an outer circumference of the cover body, and the filler metal is held in a recess defined by the cover body and the outer wall. Each of the plurality of lines branching from the bias power line has a plurality of trenches formed in an end thereof to be joined to the bias electrode, the plurality of trenches serving to accelerate capillary action during a brazing process.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view schematically showing the configuration of a substrate processing apparatus according to an embodiment of the present disclosure;

FIG. 2 is a view for explaining the structure of a substrate support unit according to an embodiment of the present disclosure;

FIG. 3 is a cross-sectional view of a substrate support unit according to a first embodiment of the present disclosure;

FIG. 4 is a graph showing temperature change in the radial direction of the substrate support unit to explain an effect of the first embodiment of the present disclosure;

FIG. 5 is a cross-sectional view of a substrate support unit according to a second embodiment of the present disclosure;

FIG. 6 is a view for explaining brazing of a bias electrode of the substrate support unit according to an embodiment of the present disclosure;

FIG. 7 is a view for explaining the structure of a brazing cover of the substrate support unit according to an embodiment of the present disclosure;

FIG. 8 is a perspective view of the brazing cover of the substrate support unit according to an embodiment of the present disclosure;

FIG. 9 is a perspective view for explaining a junction portion of a bias power lead-in line according to an embodiment of the present disclosure; and

FIG. 10 is a flowchart for explaining a method of brazing-joining the bias electrode according to an embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

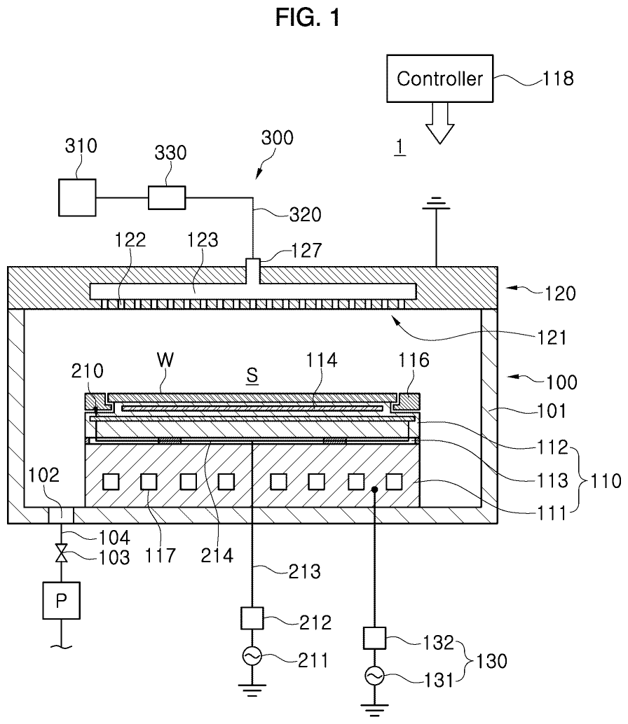

FIG. 1 is a view schematically showing the configuration of a substrate processing apparatus according to an embodiment of the present disclosure.

Referring to FIG. 1, a substrate processing apparatus 1 according to an embodiment of the present disclosure includes a process chamber 100. The process chamber 100 provides a processing space S defined in a chamber body 101 in which a substrate processing operation is performed. The chamber body 101 may be formed of a metal such as aluminum. The substrate processing operation may be a plasma treatment operation. The plasma treatment operation may be performed in a reduced-pressure atmosphere. To this end, an exhaust port 102 may be formed in the process chamber 100. The exhaust port 102 may be formed in a bottom of the process chamber. In FIG. 1, the exhaust port 102 is illustrated as a single port. However, the exhaust port 102 may be formed in a ring shape around a substrate support unit 110. The exhaust port 102 is connected to an exhaust pump P via an exhaust line 104 and an exhaust valve 103. The pressure in the processing space S in the process chamber 100 may be adjusted to a predetermined pressure by operating the exhaust pump P and adjusting the exhaust valve 103.

Inside the process chamber 100, a substrate support unit 110 is provided to support a substrate W. The substrate support unit 110 may include a base plate 111 and a dielectric plate 112 that is supported on the base plate 111 and adsorbs and fixes the substrate W. The base plate 111 and the dielectric plate 112 may be bonded to each other using an adhesive layer 113, and the adhesive layer 113 may be a silicone adhesive or the like.

The dielectric plate 112 may be formed of a dielectric material such as alumina and may be provided therein with a chucking electrode 114 to generate electrostatic force. When voltage is applied to the chucking electrode 114 by a power supply (not shown), electrostatic force is generated, and the substrate W is adsorbed on and fixed to the dielectric plate 112. The dielectric plate 112 may be provided with a heater (not shown) to adjust the temperature of the substrate W.

Inside the dielectric plate 112, a bias electrode 210 may be disposed below the chucking electrode 114 in order to control plasma process characteristics such as an etching rate. The bias electrode 210 is electrically connected to a second radio-frequency (RF) power supply 211 via a second matcher 212 to receive bias power. In the configuration shown in FIG. 1, RF power is supplied to the bias electrode 210 through a bias power line 213. However, the present disclosure is not limited thereto. A direct-current (DC) voltage may be applied to the bias electrode 210 as needed. A connection relationship between the bias electrode 210, the bias power line 213, and the second RF power supply 211 will be described in detail later.

The base plate 111 may be disposed below the dielectric plate 112 and may be formed of a metal such as aluminum. The base plate 111 may be provided therein with a coolant channel 117 through which a cooling fluid flows, and thus may perform a function of cooling the substrate W. The coolant channel 117 may be provided as a circulation passage through which the cooling fluid circulates.

The substrate support unit 110 may include a focus ring 116 surrounding the outer periphery of the dielectric plate 112. The focus ring 116 may include a stepped portion formed on an upper side thereof in order to support the outer circumferential surface of the substrate W. The focus ring 116 may be formed of a ceramic material.

A showerhead unit 120 may be provided above the process chamber 100. The showerhead unit 120 may include a shower plate 121 in which a plurality of gas supply holes 122 is formed, a gas distribution chamber 123, and a gas inlet 127. A gas supplied from a gas supply unit 300 may flow into the gas distribution chamber 123 through the gas inlet 127, and may then be supplied to the processing space S through the gas supply holes 122.

The gas supply unit 300 supplies a gas required for plasma treatment to the processing space S. The gas supply unit 300 may include a gas source 310, a gas supply line 320, and a gas flow controller 330. The gas supply line 320 may connect the gas source 310 to the gas inlet 127, and the gas flow controller 330 may adjust a flow rate of the gas flowing through the gas supply line 320 or may block the gas supply line 320.

Although one gas source 310, one gas supply line 320, and one gas flow controller 330 are illustrated in FIG. 1, the gas supply unit 300 of the present disclosure may include a plurality of gas sources configured to supply a plurality of gases to the processing space S and a plurality of gas flow controllers configured to independently control the supply of the respective gases. The plurality of gases may be etching gases used to etch a processing film formed on the substrate W. The etching gases may include, for example, fluorine (F)-based gases. In addition, the plurality of gases may further include gases containing oxygen (O), inert gases, or other gases.

A plasma generation unit 130 may include a first RF power supply 131 configured to supply RF power to generate plasma in the processing space S and a first matcher 132 for impedance matching. The first RF power supply 131 may provide RF power in a range of several hundred kHz to several hundred MHz.

The first RF power supply 131 may supply RF power to the substrate support unit 110 functioning as a lower electrode. In this case, the showerhead unit 120 functioning as an upper electrode may be grounded. Although the first RF power supply 131 is illustrated in FIG. 1 as being connected to the lower electrode, this is to be understood as an example. In order to generate plasma in the processing space S, RF power may be applied to the upper electrode, and the lower electrode may be grounded. Alternatively, RF power may be applied to both the upper electrode and the lower electrode. A plurality of RF power supplies having different frequencies may be used as the first RF power supply 131.

Although the plasma source is illustrated in FIG. 1 as being a capacitively coupled plasma (CCP) source, this is to be understood as an example. The plasma source of the present disclosure is not limited to the CCP source, and various methods capable of generating plasma, such as inductively coupled plasma (ICP), remote plasma, and microwave plasma, in the processing space S may also be applied thereto.

### First Embodiment

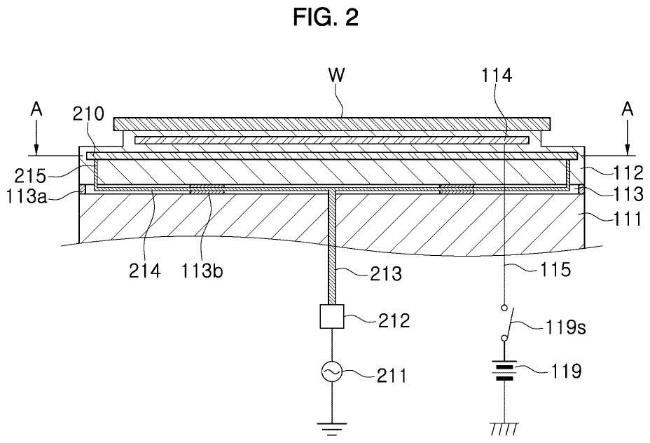

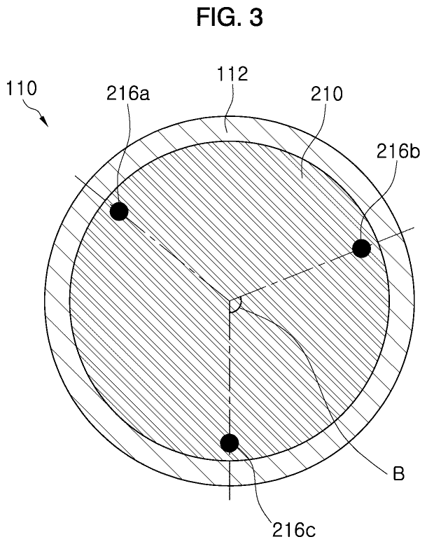

FIG. 2 is a view showing the structure of a substrate support unit according to a first embodiment of the present disclosure. FIG. 3 is a cross-sectional view of the substrate support unit according to the first embodiment of the present disclosure, taken along line A-A in FIG. 2. Components not necessary for explaining electrical connection of the bias electrode, such as the focus ring 116, are omitted. However, the technical scope of the present disclosure is not limited thereto.

Referring to FIGS. 2 and 3, in the substrate support unit 110 according to the present disclosure, the bias power line 213 for supplying RF power to the bias electrode 210 branches into a plurality of lines, and the plurality of lines is electrically connected to the bias electrode 210 in a region outside the substrate W (an external region not overlapping the substrate when viewed from above the substrate in FIG. 2). For example, as shown in FIG. 2, the bias power line 213 extends upward at a central portion of the substrate support unit 110 and then branches into a plurality of bias power distribution lines 214. The bias power distribution lines 214 extend outward in the diameter direction of the substrate support unit 110 in a region below the dielectric plate 112. It is advantageous for the bias power distribution lines 214 to be disposed inside the adhesive layer 113 for bonding the dielectric plate 112 and the base plate 111 to each other. However, the present disclosure is not limited thereto, as long as the bias power distribution lines 214 are capable of being joined from below to the bias electrode 210 included in the dielectric plate 112. In the adhesive layer 113, a plurality of first adhesive portions 113a and a plurality of second adhesive portions 113b are disposed along or between the bias power distribution lines 214 to tightly bond the dielectric plate 112 and the base plate 111 to each other.

In the first embodiment of the present disclosure, a chucking electrode 114 for adsorbing and supporting the substrate W is provided in the dielectric plate 112, and a DC power supply 119 for supplying chucking power is connected to the chucking electrode 114 via a chucking wire 115 and is controlled by a switch 119s under the control of the controller 118. The bias electrode 210 is disposed below the chucking electrode 114 at a predetermined interval. The bias electrode 210 may extend to a stepped portion of the dielectric plate 112, on which the focus ring 116 is disposed, in the diameter direction of the substrate support unit 110 in order to control movement of ions at an edge of the substrate W during a plasma process.

The bias power distribution lines 214 are electrically connected at ends thereof to bias power lead-in lines 215. The bias power lead-in lines 215 extend upward to be connected to the bias electrode 210. As described above, it is advantageous for junction portions 216 connected to the bias electrode 210 to be located in a region outside the substrate W, that is, an external region not overlapping the substrate W when viewed from above the substrate W (refer to FIG. 2).

Because the junction portions 216 connected to the bias electrode 210 are located in a region outside the substrate W, even when a high voltage is momentarily applied to the bias power line 213, a temperature change caused by heat generation does not affect the substrate W. In addition, unlike the related art, the bias power line 213 branches into a plurality of bias power distribution lines 214 having a relatively small thickness or a plurality of bias power lead-in lines 215 extending therefrom, rather than being directly connected to the bias electrode 210. Accordingly, even when a high voltage is applied to the bias power line 213, the amount of heat generated due to Joule heating is reduced.

Referring to FIG. 3, which is a cross-sectional view taken along line A-A in FIG. 2, in the first embodiment of the present disclosure, the bias electrode 210 has a substantially disc shape, and a plurality of junction portions 216 is connected to the bias power lead-in lines 215. FIG. 3 shows an embodiment in which the bias power line 213 branches into three bias power lead-in lines 215. The three bias power lead-in lines 215 form a first junction portion 216a, a second junction portion 216b, and a third junction portion 216c, respectively. Angles B formed by the plurality of junction portions 216a, 216b, and 216c and the center of the dielectric plate 112 may be equal to each other. Alternatively, the angles B may differ from each other as needed.

The plurality of junction portions 216 connected to the bias electrode 210, that is, the first junction portion 216a, the second junction portion 216b, and the third junction portion 216c, may be formed along the edge of the bias electrode 210 in a region outside the substrate W, which is an external region not overlapping the substrate W when viewed from above the substrate W.

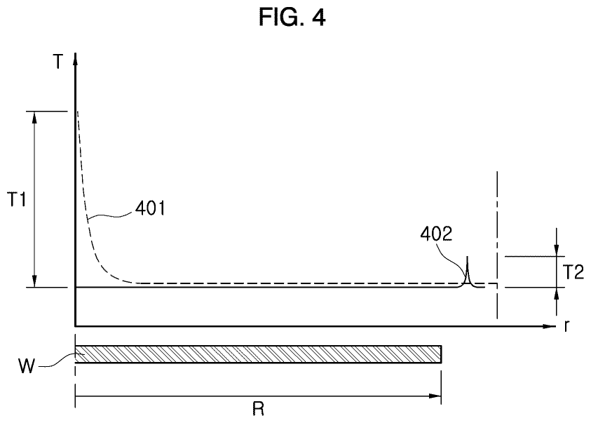

Next, the effect of the substrate support unit 110 according to the first embodiment of the present disclosure will be described with reference to FIG. 4. In the first embodiment of the present disclosure, the bias power line 213 branches into a plurality of bias power lead-in lines 215 having a relatively small diameter, and the bias power lead-in lines 215 form the junction portions 216 together with the bias electrode 210 in a region outside the substrate W. Accordingly, even when high power is applied to the bias power line 213, the substrate W is not affected by Joule heating.

In the related art, the bias power line 213 having a relatively large thickness is connected to the bias electrode 210 at the central portion of the substrate support unit 110. As shown in FIG. 4, the related art exhibits a temperature characteristic 401 in which the temperature T1 of the central portion of the substrate support unit 110 is much higher than the temperatures of other regions due to Joule heating. As a result of computer simulation performed by the applicant of the present disclosure, when bias power is supplied as process power, a temperature difference of up to 15° C. is observed. The temperature distribution at the central portion of the substrate support unit 110 directly affects the substrate W adsorbed on and supported by the substrate support unit 110, which may lead to process defects.

In contrast, in the first embodiment of the present disclosure, because the bias power line 213 branches into a plurality of lines and the plurality of lines is connected to the bias electrode 210 in a region outside the substrate W, the substrate support unit 110 exhibits a temperature characteristic 402 in which a slight peak value T2 is observed in the peripheral region of the substrate support unit 110 in which the junction portions 216 are formed, and most of the radial region R of the substrate support unit 110 in which the substrate W is supported is maintained at a constant low temperature. As a result of computer simulation performed by the applicant of the present disclosure, when bias power is supplied as process power, the maximum peak temperature difference T2 is observed to be only 1.34° C.

### Second Embodiment

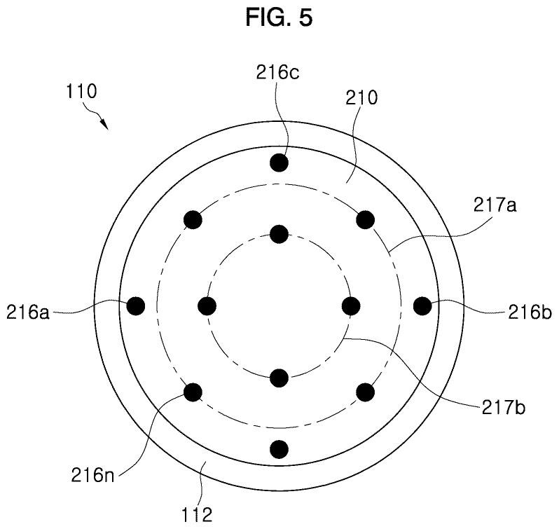

Next, a substrate support unit 110 according to a second embodiment of the present disclosure will be described in detail with reference to FIG. 5 in comparison with the first embodiment.

In the second embodiment of the present disclosure, the bias power line 213 branches into a plurality of lines, and junction portions 216 connected to the bias electrode 210 may also be formed in an internal region overlapping the substrate W. Similar to the first embodiment, the first junction portion 216a, the second junction portion 216b, and the third junction portion 216c are connected to the bias electrode 210 in a region outside the substrate W. In addition, junction portions 216n connected to the bias electrode 210 in an internal region overlapping the substrate W are further included. For example, an imaginary first layer 217a having a smaller radius than the substrate W may be formed in an internal region of the substrate support unit 110 in which the substrate W is adsorbed and supported, and a plurality of junction portions 216n may be formed on the first layer 217a. In addition, an imaginary second layer 217b having a smaller radius than the first layer 217a may be formed, and a plurality of junction portions 217n may be formed on the second layer 217b.

In the substrate support unit 110 according to the second embodiment of the present disclosure, the junction portions 216 connected to the bias electrode 210 are also disposed in an internal region overlapping the substrate W. Furthermore, because the bias power line 213 branches into a larger number of bias power lead-in lines 215 to form the junction portions 216, even when high bias power is applied, temperature does not greatly rise in an internal region overlapping the substrate W.

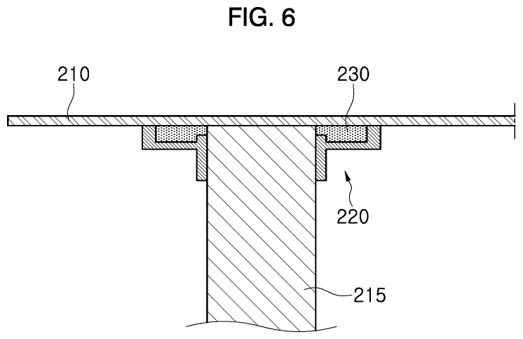

Next, a method of manufacturing the substrate support unit 110 of the present disclosure will be described in detail with reference to FIGS. 6 to 8. In particular, an embodiment of the present disclosure is directed to improving a method of brazing-joining the bias electrode 210 to the bias power lead-in lines 215 branching from the bias power line 213.

A brazing technique, in which two or more base metals are heated to a temperature of 450° C. or higher using a filler metal to be joined to each other, has been utilized as a method for electrode joining of the substrate support unit 110. Brazing has an advantage in that base metals are not melted, while a joint is achieved with strength similar to that of the base metals. However, a filler metal having properties close to those of the base metals should be selected, and attention should be paid to surface treatment because capillary action is used. In addition, during heat treatment, the melted filler metal may flow out and be lost, making it difficult to secure sufficient strength.

The present disclosure discloses a joining method that facilitates joining of the bias electrode 210 and the bias power line 213 while ensuring excellent electrical contact characteristics. A method of manufacturing the substrate support unit 110 according to an embodiment of the present disclosure requires a brazing cover 220 that assists in brazing between the bias electrode 210 and the bias power lead-in line 215. One end of the brazing cover 220 receives the bias power lead-in line 215, and the other end thereof is joined to the bias electrode 210. The bias power lead-in line 215 is supported by the brazing cover 220 to be tightly joined to the bias electrode 210, and a recess 230 formed in the brazing cover 220 is filled with a filler metal melted and solidified through brazing heat treatment, thereby providing strong mechanical joint capable of withstanding shock, vibration, thermal expansion, and contraction. In addition, when a filler metal having electrical properties similar to those of the bias electrode 210 is used, the filler metal filling the recess 230 achieves continuous and uniform joining at the connection portion, thereby minimizing electrical contact resistance and ensuring stable current flow.

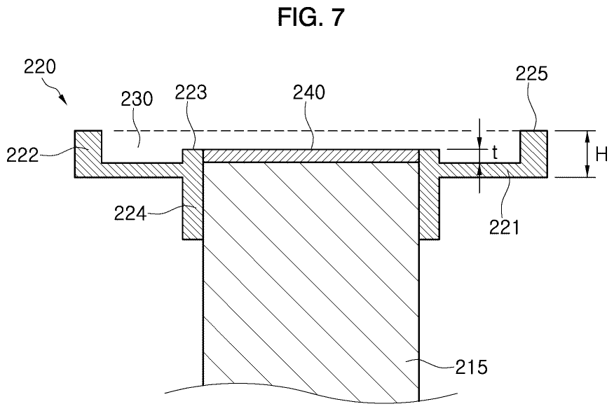

As shown in FIG. 7, the brazing cover 220 according to an embodiment of the present disclosure may include a substantially disc-shaped cover body 221 and a substantially cylindrical line holder 224 fitted into the center of the cover body 221. The bias power lead-in line 215 branching from the bias power line 213 is fitted into the line holder 224. The inner diameter of the line holder 224 may be set to allow the bias power lead-in line 215 to be press-fitted into the line holder 224. For example, the line holder 224 may serve as a cylindrical sleeve or guide tube which accommodate the bias power lead-in line 215. The bias power lead-in line 215 may be fitted into the line holder 224 by pressing so that the line holder 224 may mechanically secure and support the bias power lead-in line 215. The brazing cover 220 further includes an outer wall 222 formed to a predetermined height H along the outer circumference of the cover body 221. The cover body 221 and the outer wall 222 define the recess 230. As described above, the recess 230 functions as a space that is filled with the filler metal 240 melted through heat treatment after completion of brazing.

One end of the outer wall 222 forms an outer circumferential surface 225 having a predetermined area. In a preparation step for brazing heat treatment, the outer circumferential surface 225 may be used as a region to which an adhesive is applied in order to temporarily fix the bias electrode 210 and the bias power lead-in line 215. The adhesive may be removed by heat treatment for brazing. Examples of the adhesive may include an instant adhesive for metal, a thermally decomposable adhesive, and an epoxy adhesive.

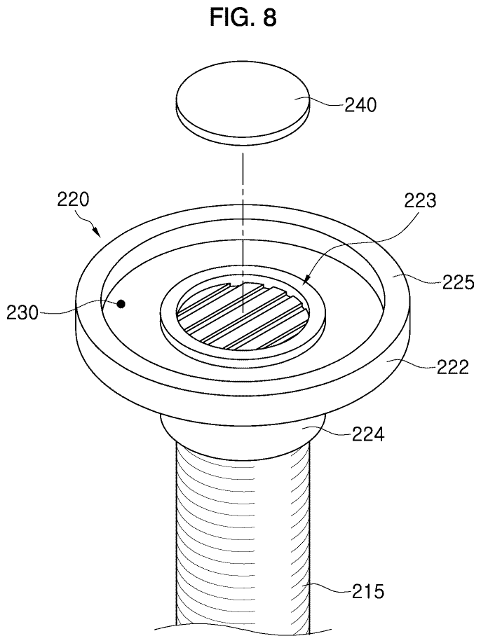

In the method of manufacturing the substrate support unit 110 according to the embodiment of the present disclosure, the brazing cover 220 further includes a protrusion 223 protruding to a predetermined height t into the recess 230. As shown in FIG. 8, the filler metal 240 may be fitted into the protrusion 223. After the bias power lead-in line 215 is fitted into the line holder 224, the filler metal 240 having a substantially disc shape may be fitted into the protrusion 223 from above the bias power lead-in line 215. In this manner, preparation for brazing may be easily completed.

In the embodiment of the present disclosure, the filler metal 240 may be selected from among aluminum, titanium, chromium, molybdenum, gold, lead, tantalum, and alloys thereof. Although the filler metal 240 has been described as having a substantially disc shape, the present disclosure is not limited thereto. The filler metal 240 may have any other shape, as long as the same is capable of being fitted into the protrusion 223 of the brazing cover 220. The filler metal 240 may be provided singularly. However, in some cases, the filler metal 240 may be provided in plural, and the plurality of filler metals 240 may be different alloys and may be fitted into the protrusion 223.

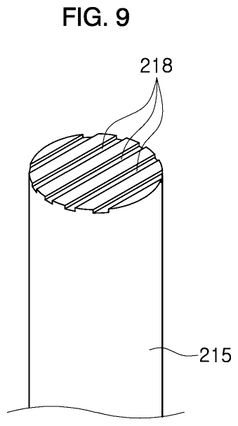

In the method of manufacturing the substrate support unit 110 according to the embodiment of the present disclosure, trenches 218 may be formed in an end of the bias power lead-in line 215 branching from the bias power line 213, as shown in FIG. 9. The trenches 218 are formed to accelerate capillary action when the filler metal 240 is melted by brazing heat treatment and flows between joining surfaces. It is advantageous for the trenches 218 to have a depth of 0.02 to 0.1 mm. If the trenches 218 are too shallow, the filler metal may not flow properly, and if the trenches 218 are too deep, joining strength may be reduced. The width of the trenches 218 may also be set to 0.02 to 0.1 mm. Although a limited number of trenches 218 is illustrated in FIG. 9, the trenches 218 may be formed over the entire area of the end of the bias power lead-in line 215.

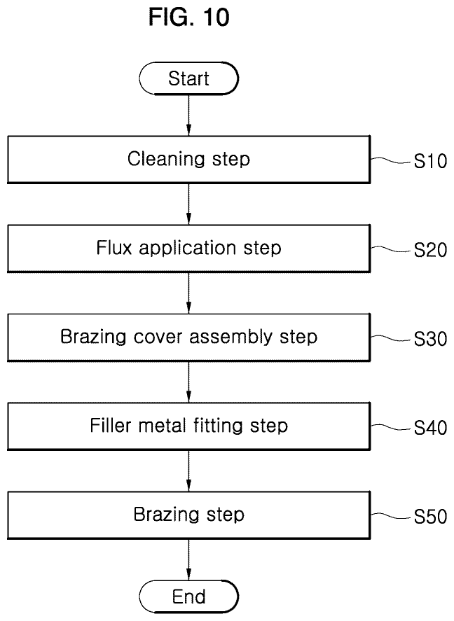

Next, the method of manufacturing the substrate support unit 110 according to the embodiment of the present disclosure will be described in more detail with reference to FIG. 10. The method of manufacturing the substrate support unit 110 according to the embodiment of the present disclosure is a method of joining a plurality of bias power lead-in lines 215, branching from the bias power line 213, to the bias electrode 210, and includes a cleaning step S10, a flux application step S20, a brazing cover assembly step S30, a filler metal fitting step S40, and a brazing step S50.

The cleaning step S10 is a step of cleaning portions of the bias electrode 210 at which the junction portions 216 are to be formed, the brazing cover 220, and the end of the bias power lead-in line 215. This step removes oil, dust, oxides, and other contaminants from the junction area to ensure that the filler metal 240 flows properly and that joining strength is not reduced by contaminants. The cleaning may be performed chemically using a degreasing agent, and in some cases, mechanical cleaning such as polishing or sanding may also be employed.

In the cleaning step S10, surface treatment of the end of the bias power lead-in line 215 that is to be joined may be further included as needed. For example, the end of the bias power lead-in line 215 may be treated to be slightly rough, rather than being completely smooth, so that capillary action occurs more effectively. It is advantageous that the surface roughness of the end be in the range of 0.4 to 1.6 micrometers in terms of arithmetic average roughness (Ra). In addition, the surface treatment may include a step of forming the trenches 218 in the end of the bias power lead-in line 215.

Subsequently, the flux application step S20 is performed. The flux application step S20 is a step of applying flux to prevent oxidation and activate a surface during a brazing heat treatment process. This step may prevent formation of oxides using flux such as borate, boron, or borax.

Subsequently, the brazing cover assembly step S30 is performed. First, the bias power lead-in line 215 is fitted into the line holder 224 of the brazing cover 220. Because the inner diameter of the line holder 224 is set to allow the bias power lead-in line 215 to be press-fitted into the line holder 224, the bias power lead-in line 215 is not easily separated once fitted. During this fitting process, an end portion of the bias power lead-in line 215 is fitted with a space left so that the filler metal 240 is fitted into the protrusion 223 of the brazing cover 220, as shown in FIG. 7.

In the subsequent filler metal fitting step S40, the substantially disc-shaped filler metal 240 is fitted into the protrusion 223 of the brazing cover 220. If the filler metal 240 is provided in plural, the fitting process is repeated so that all the filler metals 240 are fitted.

Finally, the brazing step S50 is performed. The brazing step S50 is a step of temporarily adhering the assembly of the bias power lead-in line 215 and the brazing cover 220 to the bias electrode 210 and then performing heat treatment. As described above, by temporarily adhering the brazing cover 220, the junction portion 216 may be formed at an accurate position, and a gap between surfaces to be joined may be controlled so that the filler metal 240 flows as designed. The brazing heat treatment is a process of heating a brazing region to melt the filler metal and cause the melted filler metal to flow uniformly into the junction portion. The heating may be performed using a local heat source such as a torch. Alternatively, for more precise processing, furnace heat treatment may be performed in a separate space in a vacuum or inert gas atmosphere.

In the method of manufacturing the substrate support unit 110 according to the embodiment of the present disclosure, in order to maximize the capillary action, surface treatment is performed on the end of the bias power lead-in line 215, and the trenches 218 are formed in the end thereof, thereby causing the filler metal 240 to uniformly spread in the junction region to achieve strong joint. Furthermore, the melted filler metal 240 does not flow downward to the outside but remains and solidifies within the recess 230 in the brazing cover 220, which is one of the unique technical features of the present disclosure, thereby increasing the mechanical and electrical connection strength of the junction portion 216.

As is apparent from the above description, according to an embodiment of the present disclosure, a single bias power line extending at a central portion of a substrate support unit branches into a plurality of lines, thereby addressing a heat generation issue occurring at a junction portion of a bias electrode when power is applied thereto.

According to an embodiment of the present disclosure, the amount of heat generated may be reduced by distributing current flowing through the bias power line, and temperature non-uniformity of a substrate may be minimized by connecting the plurality of lines branching from the bias power line to the bias electrode in a region outside the substrate.

According to an embodiment of the present disclosure, the bias power line branches into a plurality of lines having a reduced diameter, so fabrication of the substrate support unit may be facilitated, and space efficiency may be improved while maintaining the same performance.

According to an embodiment of the present disclosure, when the bias electrode and the bias power line are joined to each other through brazing, heat treatment may be facilitated, and joining accuracy may be improved.

Although the exemplary embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. A substrate support unit disposed inside a chamber body for processing of a substrate using plasma to hold the substrate, the substrate support unit comprising:
a dielectric plate comprising a chucking electrode for adsorption of the substrate;
a bias electrode provided inside the dielectric plate at a position below the chucking electrode to control plasma treatment process characteristics; and
a bias power line configured to supply power to the bias electrode,
wherein the bias power line branches into a plurality of lines, and the plurality of lines forms junction portions together with the bias electrode in a region outside the substrate.

2. The substrate support unit as claimed in claim 1, wherein the power supplied through the bias power line is supplied by a direct-current power supply or a radio-frequency power supply.

3. The substrate support unit as claimed in claim 1, further comprising:
a base plate disposed below the dielectric plate, the base plate functioning as a support; and
an adhesive layer joining the dielectric plate and the base plate to each other,
wherein the plurality of lines branching from the bias power line is arranged inside the adhesive layer and extends to the junction portions with the bias electrode.

4. The substrate support unit as claimed in claim 1, wherein the bias electrode extends in a diameter direction to an edge of the substrate.

5. The substrate support unit as claimed in claim 1, wherein the bias power line branches into additional lines, and the additional lines form the junction portions together with the bias electrode in a region inside the substrate.

6. The substrate support unit as claimed in claim 1, wherein the junction portions are formed through brazing.

7. The substrate support unit as claimed in claim 6, further comprising a brazing cover provided at each of the junction portions, the brazing cover being configured to hold a filler metal, melted by brazing, at each of the junction portions.

8. The substrate support unit as claimed in claim 7, wherein the brazing cover comprises:
a cover body having a disc shape;
a line holder formed at a central portion of the cover body so as to receive the bias power line fitted thereinto; and
an outer wall extending along an outer circumference of the cover body, and
wherein the filler metal is held in a recess defined by the cover body and the outer wall.

9. The substrate support unit as claimed in claim 8, wherein the outer wall has an end forming an outer circumferential surface to allow an adhesive for brazing to be applied thereto.

10. The substrate support unit as claimed in claim 7, wherein the filler metal is selected from among aluminum, titanium, chromium, molybdenum, gold, lead, and tantalum.

11. The substrate support unit as claimed in claim 8, wherein the brazing cover further comprises a protrusion protruding into the recess so as to allow the filler metal to be fitted into the protrusion before brazing heat treatment.

12. The substrate support unit as claimed in claim 6, wherein each of the plurality of lines branching from the bias power line has a plurality of trenches formed in an end thereof to be joined to the bias electrode, the plurality of trenches serving to accelerate capillary action during a brazing process.

13. The substrate support unit as claimed in claim 12, wherein each of the plurality of trenches has a depth of 0.02 to 0.1 mm.

14. A substrate processing apparatus comprising:
a chamber body for processing of a substrate using plasma; and
a substrate support unit disposed inside the chamber body to hold the substrate,
wherein the substrate support unit comprises:
a dielectric plate comprising a chucking electrode for adsorption of the substrate;
a bias electrode provided inside the dielectric plate at a position below the chucking electrode to control plasma treatment process characteristics; and
a bias power line configured to supply power to the bias electrode, and
wherein the bias power line branches into a plurality of lines, and the plurality of lines forms junction portions together with the bias electrode in a region outside the substrate.

15. The substrate processing apparatus as claimed in claim 14, wherein the substrate support unit further comprises:
a base plate disposed below the dielectric plate, the base plate functioning as a support; and
an adhesive layer joining the dielectric plate and the base plate to each other, and
wherein the plurality of lines branching from the bias power line is arranged inside the adhesive layer and extends to the junction portions with the bias electrode.

16. The substrate processing apparatus as claimed in claim 14, wherein the bias electrode extends in a diameter direction to an edge of the substrate.

17. The substrate processing apparatus as claimed in claim 14, wherein the junction portions are formed through brazing,
wherein the substrate support unit further comprises a brazing cover provided at each of the junction portions, the brazing cover being configured to hold a filler metal, melted by brazing, at each of the junction portions,
wherein the brazing cover comprises:
a cover body having a disc shape;
a line holder formed at a central portion of the cover body so as to receive the bias power line fitted thereinto; and
an outer wall extending along an outer circumference of the cover body, and
wherein the filler metal is held in a recess defined by the cover body and the outer wall.

18. The substrate processing apparatus as claimed in claim 17, wherein each of the junction portions is formed by performing:
a cleaning step of removing contaminants from the bias electrode, the brazing cover, and the bias power line;
a flux application step for prevention of oxidation during brazing heat treatment;
a brazing cover assembly step of fitting an end of the bias power line to be joined into the line holder;
a filler metal fitting step of fitting the filler metal into a protrusion protruding from an end of the line holder into the recess; and
a brazing step of performing heat treatment to form each of the junction portions.

19. The substrate processing apparatus as claimed in claim 18, wherein the brazing step comprises a step of temporarily adhering an assembly of the brazing cover and the bias power line at a position for formation of each of the junction portions of the bias electrode.

20. A substrate processing apparatus comprising:
a chamber body for processing of a substrate using plasma; and
a substrate support unit disposed inside the chamber body to hold the substrate,
wherein the substrate support unit comprises:
a dielectric plate comprising a chucking electrode for adsorption of the substrate;
a base plate disposed below the dielectric plate, the base plate functioning as a support;
an adhesive layer joining the dielectric plate and the base plate to each other;
a bias electrode provided inside the dielectric plate at a position below the chucking electrode to control plasma treatment process characteristics, the bias electrode extending in a diameter direction to an edge of the substrate adsorbed on and held by the dielectric plate; and
a bias power line configured to supply power to the bias electrode,
wherein the bias power line branches into a plurality of lines, and the plurality of lines forms a plurality of junction portions together with the bias electrode in a region outside the substrate and a region inside the substrate,
wherein the plurality of lines branching from the bias power line is arranged inside the adhesive layer and extends to the plurality of junction portions with the bias electrode,
wherein the plurality of junction portions is formed through brazing,
wherein the substrate support unit further comprises a brazing cover provided at each of the plurality of junction portions, the brazing cover being configured to hold a filler metal, melted by heat treatment, at each of the plurality of junction portions,
wherein the brazing cover comprises:
a cover body having a disc shape;
a line holder formed at a central portion of the cover body so as to receive the bias power line fitted thereinto; and
an outer wall extending along an outer circumference of the cover body,
wherein the filler metal is held in a recess defined by the cover body and the outer wall, and
wherein each of the plurality of lines branching from the bias power line has a plurality of trenches formed in an end thereof to be joined to the bias electrode, the plurality of trenches serving to accelerate capillary action during a brazing process.
